(19) United States
(12) Patent Application Publication
(10) Pub. No.: US 2026/0099090 A1
(43) Pub. Date: Apr. 9, 2026

(54) REFLECTIVE MASK BLANK, METHOD FOR MANUFACTURING REFLECTIVE MASK BLANK, AND METHOD FOR MANUFACTURING REFLECTIVE MASK

(71) Applicant: AGC Inc., Tokyo (JP)

(72) Inventors: Yuya NAGATA, Tokyo (JP); Eita NAKANISHI, Tokyo (JP); Kenichi SASAKI, Tokyo (JP)

(73) Assignee: AGC Inc., Tokyo (JP)

(21) Appl. No.: 19/355,446

(22) Filed: Oct. 10, 2025

Related U.S. Application Data
(63) Continuation of application No. PCT/JP2024/015451, filed on Apr. 18, 2024.

(30) Foreign Application Priority Data
Apr. 28, 2023 (JP) 2023-074391

(51) Int. Cl. G03F 1/24

(52) U.S. Cl. CPC G03F 1/24

(57) ABSTRACT

An object of the present invention is to provide a technology for improving processing accuracy of an opening pattern of the phase shift film. A reflective mask blank (1) includes a substrate (10), a multilayer reflective film (11), a protective film (12), a phase shift film (13), a first hard mask film (14), and a second hard mask film (15) in this order. The first hard mask film (14) has higher resistance to a first etching gas containing a fluorine-based gas compared with the phase shift film (13). The second hard mask film (15) has higher resistance to a second etching gas containing an oxygen-based gas and a chlorine-based gas compared with the first hard mask film (14). The second hard mask film (15) and the first hard mask film (14) have a selectivity of 5 or more with respect to the second etching gas.

This application is a continuation application of International Application No. PCT/JP2024/015451, filed on Apr. 18, 2024, which claims priority of Japanese Patent application No. 2023-074391, filed on Apr. 28, 2023, the entire contents of which are incorporated therein by reference.

### TECHNICAL FIELD

The present disclosure relates to a reflective mask blank, a method for manufacturing a reflective mask blank, and a method for manufacturing a reflective mask.

### BACKGROUND ART

In recent years, with the miniaturization of semiconductor devices, extreme ultraviolet lithography (EUVL), which is an exposure technology using extreme ultraviolet rays (EUV), has been developed. EUV includes soft X-rays and vacuum ultraviolet rays, and specifically, is light having a wavelength of approximately 0.2 nm to 100 nm. At present, EUV having a wavelength of approximately 13.5 nm is mainly being studied.

In EUVL, a reflective mask is used. The reflective mask includes a substrate such as a glass substrate, a multilayer reflective film that reflects EUV light, a protective film that protects the multilayer reflective film, and an absorption film that absorbs EUV light in this order. The absorption film may not only absorb the EUV light but also shift a phase of the EUV light. That is, the absorption film may be a phase shift film. An opening pattern is formed in the absorption film. In EUVL, the opening pattern of the absorption film is transferred to a target substrate such as a semiconductor substrate. The transferring includes transferring by reduction.

A method for manufacturing a reflective mask described in Patent Document 1 includes transferring an opening pattern of a resist film to an etching mask film corresponding to a hard mask film, and transferring the opening pattern of the etching mask film to an absorption film. The absorption film contains at least one selected from iridium (Ir) and ruthenium (Ru). The etching mask film contains tantalum (Ta) or silicon (Si), and further contains at least one selected from oxygen (O), nitrogen (N), carbon (C), boron (B), and hydrogen (H).

### CITATION LIST

### Patent Document

Patent Document 1: PCT International Publication No. WO2022/065421

### SUMMARY OF INVENTION

### Technical Problem

A noble metal element has been studied as a material of the phase shift film. The noble metal element is, for example, Ir, Pt, Pd, Ag, or Au. These noble metal elements have a slow etching rate. Therefore, thickening of the hard mask film is considered to secure processing time during processing of the phase shift film.

In a case where the hard mask film is thickened, the processing time of the hard mask film is lengthened during the processing. In the related art, during the processing of the hard mask film, a line width of a resist film may be narrowed with the passage of time. This is because an oxygen radical etches a side surface of an opening of the resist film during the processing of the hard mask film.

In a case where the line width of the resist film decreases with the passage of time during the processing of the hard mask film, the side surface of the opening of the hard mask film is inclined. In a case where the phase shift film is processed using the hard mask film having such an opening, a side surface of an opening of a phase shift film is also inclined.

An aspect of the present disclosure provides a technology for improving processing accuracy of an opening pattern of the phase shift film.

### Solution to Problem

A reflective mask blank according to one aspect of the present disclosure includes a substrate, a multilayer reflective film, a protective film, a phase shift film, a first hard mask film, and a second hard mask film in this order. The multilayer reflective film reflects EUV light. The protective film protects the multilayer reflective film from a first etching gas during processing of the phase shift film. The phase shift film absorbs the EUV light and shifts a phase of the EUV light. The first hard mask film protects part of the phase shift film from the first etching gas during the processing of the phase shift film. The second hard mask film protects part of the first hard mask film from a second etching gas during processing of the first hard mask film. The first hard mask film has higher resistance to the first etching gas containing a fluorine-based gas compared with the phase shift film. The second hard mask film has higher resistance to the second etching gas containing an oxygen-based gas and a chlorine-based gas compared with the first hard mask film. A selectivity (ER1/ER2) of the second hard mask film and the first hard mask film to the second etching gas is 5 or more. ER1 is an etching rate of the first hard mask film, and ER2 is an etching rate of the second hard mask film.

### Advantageous Effects of Invention

According to one aspect of the present disclosure, the second hard mask film is provided on a side opposite to the phase shift film with the first hard mask film set as a reference. As a result, the processing accuracy of the opening pattern of the first hard mask film can be improved, and thus the processing accuracy of the opening pattern of the phase shift film can be improved.

### BRIEF DESCRIPTION OF DRAWINGS

FIG. 1 A cross-sectional view showing a reflective mask blank according to an embodiment.

FIG. 2 A flowchart showing a method for manufacturing the reflective mask blank according to the embodiment.

FIG. 3 A cross-sectional view showing a reflective mask according to the embodiment.

FIG. 4 A flowchart showing a method for manufacturing the reflective mask according to the embodiment.

FIG. 5A is a cross-sectional view showing an example of preparation of a substrate.

FIG. 5B is a cross-sectional view showing an example at the end of processing of a second hard mask film.

FIG. 5C is a cross-sectional view showing an example at the end of processing of a first hard mask film.

FIG. 5D is a cross-sectional view showing an example at the end of processing of a phase shift film.

FIG. 6A is a cross-sectional view showing an example of preparation of a substrate in the related art.

FIG. 6B is a cross-sectional view showing an example during processing of the first hard mask film in the related art.

FIG. 6C is a cross-sectional view showing an example at the end of processing of the first hard mask film in the related art.

FIG. 6D is a cross-sectional view showing an example during processing of the phase shift film in the related art.

FIG. 6E is a cross-sectional view showing an example at the end of processing of phase shift film in the related art.

FIG. 7 A cross-sectional view showing an example of EUV light reflected from the reflective mask in FIG. 3.

FIG. 8 An exaggerated cross-sectional view showing an example of a shape of the first hard mask film at the end of the processing of the first hard mask film.

### DESCRIPTION OF EMBODIMENTS

Hereinafter, embodiments for carrying out the present disclosure will be described with reference to the drawings. The same reference numerals are assigned to the same or corresponding configurations in the drawings, and description thereof may be omitted. In the specification, “to” indicating a numerical range means that the numerical range includes numerical values described before and after “to” as a lower limit value and an upper limit value.

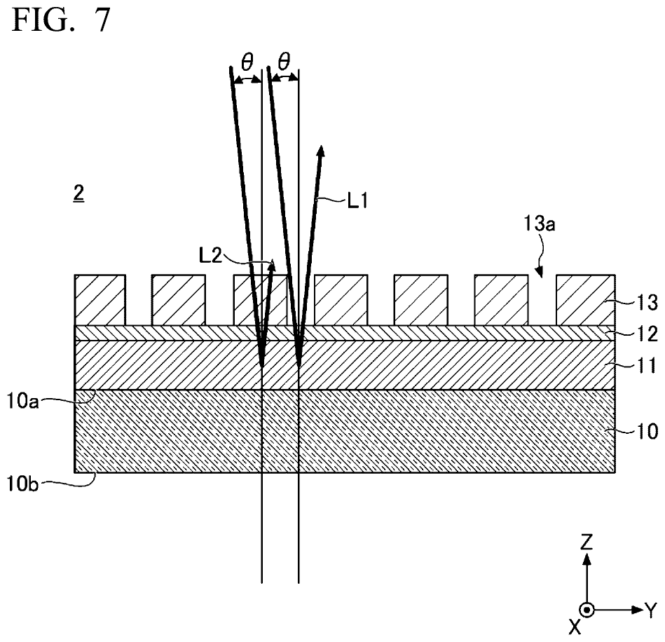

In each drawing, an X-axis direction, a Y-axis direction, and a Z-axis direction are directions orthogonal to each other. The Z-axis direction is a direction orthogonal to a first main surface 10a of a substrate 10. The X-axis direction is a direction orthogonal to an incident surface (a surface including an incident ray and a reflected ray) of the EUV light. As shown in FIG. 7, the incident ray is inclined in a positive Y-axis direction as the incident ray is directed in a negative Z-axis direction, and the reflected ray is inclined in the positive Y-axis direction as the reflected ray is directed in the positive Z-axis direction.

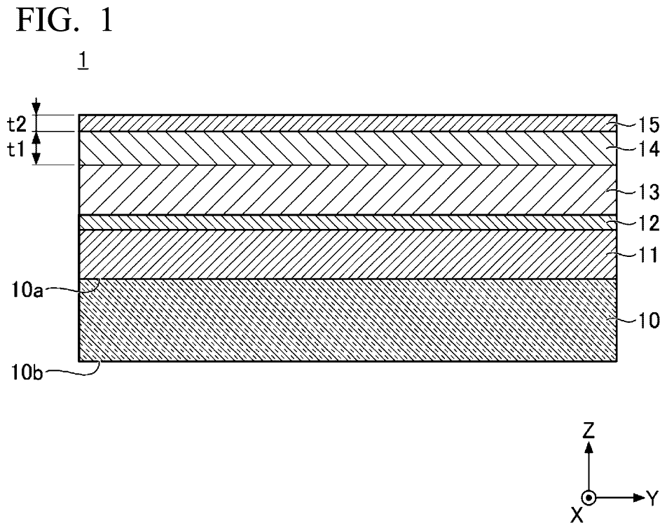

A reflective mask blank 1 according to one embodiment will be described with reference to FIG. 1. The reflective mask blank 1 includes, for example, a substrate 10, a multilayer reflective film 11, a protective film 12, a phase shift film 13, a first hard mask film 14, and a second hard mask film 15 in this order. The multilayer reflective film 11, the protective film 12, the phase shift film 13, the first hard mask film 14, and the second hard mask film 15 are formed on a first main surface 10a of the substrate 10 in this order. The multilayer reflective film 11 reflects EUV light. The protective film 12 protects the multilayer reflective film 11 from a first etching gas during processing of the phase shift film 13. The phase shift film 13 absorbs EUV light and shifts a phase of the EUV light. The first hard mask film 14 protects part of the phase shift film 13 from the first etching gas during the processing of the phase shift film 13. The second hard mask film 15 protects part of the first hard mask film 14 from a second etching gas during processing of the first hard mask film 14.

The reflective mask blank 1 may further include a functional film (not shown in FIG. 1). For example, the reflective mask blank 1 may include a conductive film on a side opposite to the multilayer reflective film 11 with the substrate 10 set as a reference. The conductive film is formed on a second main surface 10b of the substrate 10. The second main surface 10b is a surface facing a side opposite to the first main surface 10a. The conductive film is used, for example, to adsorb a reflective mask 2 to an electrostatic chuck of an exposure device. The reflective mask blank 1 may include a diffusion barrier film (not shown) between the multilayer reflective film 11 and the protective film 12. The diffusion barrier film suppresses a metal element contained in the protective film 12 from diffusing to the multilayer reflective film 11.

Although not shown in the drawing, the reflective mask blank 1 may include a buffer film between the protective film 12 and the phase shift film 13. The buffer film protects the protective film 12 from the first etching gas for forming an opening pattern 13a in the phase shift film 13. The buffer film is etched more slowly compared with the phase shift film 13. Unlike the protective film 12, the buffer film finally has the same opening pattern as the opening pattern 13a of the phase shift film 13.

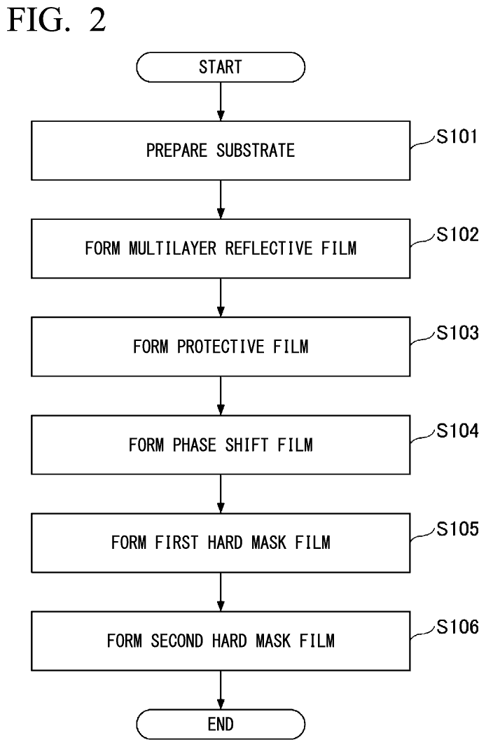

Next, a method for manufacturing the reflective mask blank 1 according to the embodiment will be described with reference to FIG. 2. The method for manufacturing the reflective mask blank 1 includes, for example, steps S101 to S106 shown in FIG. 2. In step S101, the substrate 10 is prepared. In step S102, the multilayer reflective film 11 is formed on the first main surface 10a of the substrate 10. In step S103, the protective film 12 is formed on the multilayer reflective film 11. In step S104, the phase shift film 13 is formed on the protective film 12. In step S105, the first hard mask film 14 is formed on the phase shift film 13. In step S106, the second hard mask film 15 is formed on the first hard mask film 14. The method for manufacturing the reflective mask blank 1 may further include a step of forming the functional film (not shown in FIG. 2).

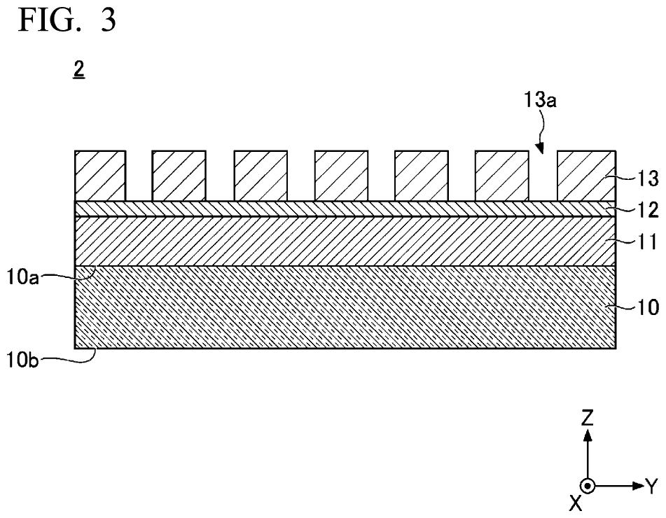

Next, the reflective mask 2 according to the embodiment will be described with reference to FIG. 3. The reflective mask 2 is manufactured by using, for example, the reflective mask blank 1 shown in FIG. 1, and includes the opening pattern 13a in the phase shift film 13. In EUVL, the opening pattern 13a of the phase shift film 13 is transferred to a target substrate such as a semiconductor substrate. The transferring includes transferring by reduction. The first hard mask film 14 and the second hard mask film 15 shown in FIG. 1 are not included in the reflective mask 2.

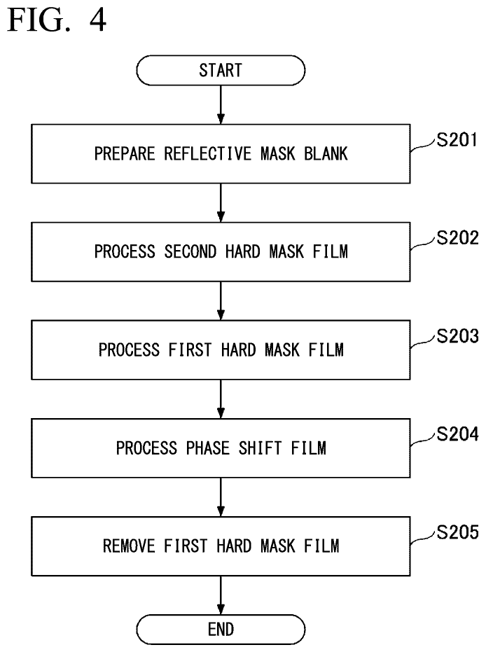

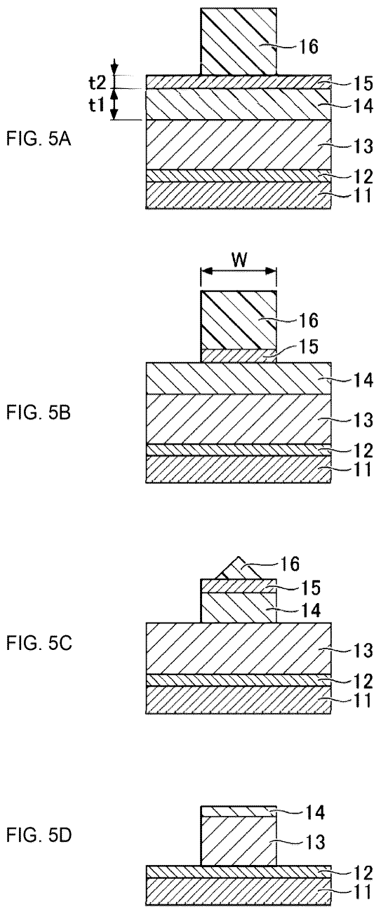

Next, a method for manufacturing the reflective mask 2 according to the embodiment will be described with reference to FIG. 4 and FIGS. 5A-5D. The method for manufacturing the reflective mask 2 has steps S201 to S205 shown in FIG. 4. In step S201, as shown in FIG. 5A, the reflective mask blank 1 is prepared. The reflective mask blank 1 includes a resist film 16 as shown in FIG. 5A. The resist film 16 is formed on the second hard mask film 15. An opening pattern to be transferred to the phase shift film 13 is formed on the resist film 16.

In step S202, as shown in FIG. 5B, the second hard mask film 15 is processed using the resist film 16 having the opening pattern. In the opening of the resist film 16, the second hard mask film 15 is exposed to a third etching gas, and the third etching gas etches the second hard mask film 15. At the end of step S202, the resist film 16 remains. As a result, the opening pattern of the resist film 16 is transferred to the second hard mask film 15.

The third etching gas contains a fluorine-based gas. The fluorine-based gas includes at least one selected from a CF₄ gas, a CHF₃ gas, a C₂F₆ gas, a C₃F₆ gas, a C₄F₆ gas, a C₄F₈ gas, a CH₂F₂ gas, a CH₃F gas, a C₃F₈ gas, an F₂ gas, an SF₆ gas, and an NF₃ gas. The third etching gas may contain an inert gas in addition to the fluorine-based gas. The inert gas includes, for example, at least one selected from an N₂ gas, an He gas, and an Ar gas. It is preferable that the third etching gas not substantially contain an oxygen-based gas unlike the second etching gas to suppress a line width W of the resist film 16 from becoming narrow. The oxygen-based gas is an O₂ gas, an O₃ gas, or a mixed gas thereof. The content of the oxygen-based gas in the third etching gas is preferably 0.5% by volume or less. It is preferable that the third etching gas be plasma-processed.

In step S203, as shown in FIG. 5C, the first hard mask film 14 is processed using the second hard mask film 15 having an opening pattern. In the opening of the second hard mask film 15, the first hard mask film 14 is exposed to the second etching gas, and the second etching gas etches the first hard mask film 14. The second hard mask film 15 has higher resistance to the second etching gas compared with the first hard mask film 14. At the end of step S203, the second hard mask film 15 remains. As a result, the opening pattern of the second hard mask film 15 is transferred to the first hard mask film 14.

The second etching gas contains a chlorine-based gas and an oxygen-based gas. The chlorine-based gas includes, for example, at least one selected from a Cl₂ gas, an SiCl₄ gas, a CHCl₃ gas, a CCl₄ gas, and a BCl₃ gas. The oxygen-based gas includes, for example, at least one selected from an O₂ gas and an O₃ gas. The second etching gas may contain an inert gas in addition to the chlorine-based gas and the oxygen-based gas. The inert gas includes, for example, at least one selected from an N₂ gas, an He gas, and an Ar gas. It is preferable that the second etching gas be plasma-processed.

The second hard mask film 15 may be removed after step S203 and before step S204. To remove the second hard mask film 15, for example, a fluorine-based gas is used similarly to the third etching gas. The fluorine-based gas includes at least one selected from a CF₄ gas, a CHF₃ gas, a C₂F₆ gas, a C₃F₆ gas, a C₄F₆ gas, a C₄F₈ gas, a CH₂F₂ gas, a CH₃F gas, a C₃F₈ gas, an F₂ gas, an SF₆ gas, and an NF₃ gas. The fluorine-based gas may further contain an inert gas. It is preferable that the fluorine-based gas be plasma-processed. Chemical solutions may be used for removing the second hard mask film 15.

In step S204, as shown in FIG. 5D, the phase shift film 13 is processed using the first hard mask film 14 having an opening pattern. In the opening of the first hard mask film 14, the phase shift film 13 is exposed to the first etching gas, and the first etching gas etches the phase shift film 13. The first hard mask film 14 has higher resistance to the first etching gas compared with the phase shift film 13. At the end of step S204, the first hard mask film 14 remains. As a result, the opening pattern of the first hard mask film 14 is transferred to the phase shift film 13.

The first etching gas contains a fluorine-based gas. The fluorine-based gas includes at least one selected from a CF₄ gas, a CHF₃ gas, a C₂F₆ gas, a C₃F₆ gas, a C₄F₆ gas, a C₄F₈ gas, a CH₂F₂ gas, a CH₃F gas, a C₃F₈ gas, an F₂ gas, an SF₆ gas, and an NF₃ gas. The first etching gas may contain an active gas or an inert gas in addition to the fluorine-based gas. The active gas includes, for example, O₂ gas. The inert gas includes, for example, at least one selected from an N₂ gas, an He gas, and an Ar gas. It is preferable that the first etching gas be plasma-processed.

In step S205, although not shown in the drawing, the first hard mask film 14 is removed. For the removal of the first hard mask film 14, for example, a fourth etching gas is used. Similar to the second etching gas, the fourth etching gas contains a chlorine-based gas and an oxygen-based gas. The fourth etching gas may further contain an inert gas. It is preferable that the fourth etching gas be plasma-processed. Chemical solutions may be used for removing the first hard mask film 14.

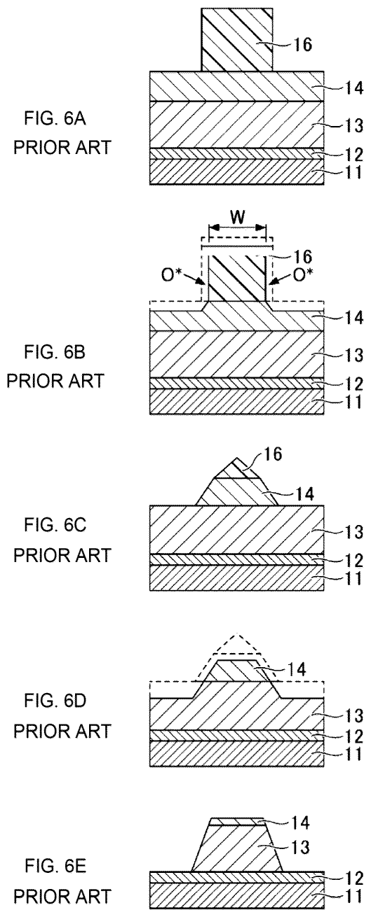

Next, a processing procedure of the reflective mask blank 1 in an example in the related art will be described with reference to FIGS. 6A-6E. As shown in FIG. 6A, a reflective mask blank 1 of the example in the related art includes the substrate 10, the multilayer reflective film 11, the protective film 12, the phase shift film 13, the first hard mask film 14, and the resist film 16 in this order. The reflective mask blank 1 of the example in the related art does not include the second hard mask film 15 between the first hard mask film 14 and the resist film 16.

The phase shift film 13 preferably contains a noble metal element. The noble metal element is, for example, Ir, Pt, Pd, Ag, or Au. Since these noble metal elements have a relatively small refractive index, the film thickness of the phase shift film 13 can be reduced while securing a phase difference. However, these noble metal elements have a slow etching rate. Therefore, thickening of the first hard mask film 14 is considered in order to secure processing time during processing of the phase shift film 13.

In a case where the first hard mask film 14 is thickened, the processing time of the first hard mask film 14 is lengthened during the processing. In the related art, as shown in FIG. 6B, during the processing of the first hard mask film 14, a line width W of the resist film 16 may become narrower with the passage of time. This is because oxygen radicals etch a side surface of an opening of the resist film 16 during the processing of the first hard mask film 14.

As shown in FIG. 6B and FIG. 6C, the line width W of the resist film 16 becomes narrower with the passage of time during the processing of the first hard mask film 14, and thus a side surface of an opening of the first hard mask film 14 is inclined. In a case where the phase shift film 13 is processed using the first hard mask film 14 having such an opening, a side surface of an opening of the phase shift film 13 is also inclined as shown in FIG. 6D and FIG. 6E.

This is because the first hard mask film 14 has a trapezoidal cross-sectional shape as shown in FIG. 6C. At a position where the film thickness of the first hard mask film 14 is small, as shown in FIG. 6D, disappearance of the first hard mask film 14 is faster and etching of the phase shift film 13 starts faster compared with a position where the film thickness of the first hard mask film 14 is large. As a result, the side surface of the opening of the phase shift film 13 is also inclined.

Next, a processing procedure of the reflective mask blank 1 of the example will be described again with reference to FIGS. 5A-5D. As shown in FIG. 5A, the reflective mask blank 1 of the example includes the second hard mask film 15 between the first hard mask film 14 and the resist film 16. As shown in FIG. 5B, the second hard mask film 15 is processed using the resist film 16 having an opening pattern.

In the opening of the resist film 16, the second hard mask film 15 is exposed to a third etching gas, and the third etching gas etches the second hard mask film 15. Since the third etching gas does not substantially contain an oxygen-based gas, oxygen radicals do not etch the side surface of the opening of the resist film 16.

Therefore, during processing of the second hard mask film 15, it is possible to suppress the line width W of the resist film 16 from becoming narrower with the passage of time, and it is possible to suppress the side surface of the opening of the second hard mask film 15 from being inclined. Therefore, as shown in FIG. 5C, the first hard mask film 14 can be processed using the second hard mask film 15 having an opening having a side surface orthogonal to the opening, and inclination of the side surface of the opening of the first hard mask film 14 can be suppressed.

The second hard mask film 15 has higher resistance to the second etching gas compared with the first hard mask film 14. The second hard mask film 15 and the first hard mask film 14 preferably have a selectivity (ER1/ER2) of 5 or more with respect to the second etching gas. ER1 is an etching rate of the first hard mask film 14, and ER2 is an etching rate of the second hard mask film 15. The selectivity (ER1/ER2) is more preferably 10 or more, still more preferably 20 or more, particularly preferably 30 or more, and most preferably 50 or more. The selectivity (ER1/ER2) is preferably 1,000 or less, more preferably 500 or less, and still more preferably 200 or less.

Here, the second etching gas is not particularly limited, but contains, for example, 50% by volume to 99% by volume of Cl₂ gas and 1% by volume to 50% by volume of O₂ gas. In this composition range, there may be at least one composition in which the selectivity (ER1/ER2) is 5 or more. The second etching gas contains an oxygen-based gas differently from the third etching gas.

In a case where the selectivity (ER1/ER2) is 5 or more, it is possible to suppress the line width of the second hard mask film 15 from becoming narrower with the passage of time during the processing of the first hard mask film 14, and it is possible to suppress the side surface of the opening of the first hard mask film 14 from being inclined.

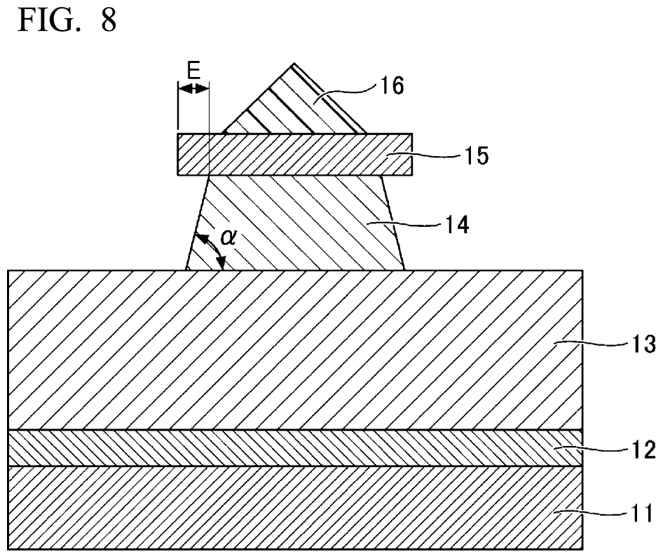

FIG. 8 shows an exaggerated example of a shape of the first hard mask film 14 at the end of the processing of the first hard mask film 14. The shape of the first hard mask film 14 can be evaluated by a taper angle α and a side etching amount E shown in FIG. 8. Note that the side etching amount is also referred to as an undercut amount.

The taper angle α is an angle formed by a boundary line between the first hard mask film 14 and the phase shift film 13 and a side surface of the opening of the first hard mask film 14. The taper angle α is preferably 70° to 90° and more preferably 80° to 90°. The larger the taper angle α, the more preferable, and the taper angle α may be 90°.

The side etching amount E is a shift amount of the side surface of the opening of the first hard mask film 14 with respect to the side surface of the opening of the second hard mask film 15 on a boundary line between the second hard mask film 15 and the first hard mask film 14. The side etching amount E is preferably 0 nm to 10 nm and more preferably 0 nm to 5 nm. The smaller the side etching amount E, the more preferable, and the side etching amount E may be 0 nm.

According to the present embodiment, the phase shift film 13 can be processed using the first hard mask film 14 having an opening with a side surface orthogonal to the opening as shown in FIG. 5D, and the inclination of the side surface of the opening of the phase shift film 13 can be suppressed. Accordingly, the processing accuracy of the opening pattern of the phase shift film 13 can be improved.

The first hard mask film 14 has higher resistance to the first etching gas compared with the phase shift film 13. The first hard mask film 14 and the phase shift film 13 have a selectivity (ER3/ER4) of 2 or more with respect to the first etching gas. ER3 is an etching rate of the phase shift film 13, and ER4 is an etching rate of the first hard mask film 14. The selectivity (ER3/ER4) is more preferably 3 or more and still more preferably 4 or more. The selectivity (ER3/ER4) is preferably 1,000 or less.

Here, the first etching gas is not particularly limited, but contains, for example, 50% by volume to 99% by volume of a CF₄ gas and 1% by volume to 50% by volume of an O₂ gas. Within this composition range, there may be at least one composition in which the selectivity (ER3/ER4) is 2 or more. The first etching gas may contain an oxygen-based gas unlike the third etching gas.

In a case where the selectivity (ER3/ER4) is 2 or more, it is possible to suppress the line width of the first hard mask film 14 from becoming narrower with the passage of time during the processing of the phase shift film 13, and it is possible to suppress the side surface of the opening of the phase shift film 13 from being inclined.

It is preferable that the first hard mask film 14 contain, as the metal element, an element X1 having a melting point T1 of 250° C. or higher for a fluoride having a valence of 4 or less. In a case where the melting point T1 is 250° C. or higher, the etching rate ER4 of the first hard mask film 14 is slow, the selectivity (ER3/ER4) is sufficiently large, and the processing of the phase shift film 13 is easy. The melting point T1 is preferably 3,000° C. or lower. Table 1 shows the melting points of fluorides under atmospheric pressure.

TABLE 1

Compound

| | Chemical | | Melting point |
|---|---|---|---|
| Pure substance | Formula | Valence | [° C.] |
| Ru | RuF₃ | 3 | >650 |
| | RuF₄ | 4 | >280 |
| Cr | CrF₂ | 2 | 894 |
| | CrF₃ | 3 | 1425 |
| | CrF₄ | 4 | 277 |
| Hf | HfF₄ | 4 | 310 |
| Al | AlF₃ | 3 | 1291 |
| Mo | MoF₃ | 3 | >600 |

As shown in Table 1, Cr, Ru, Al, and Hf have a melting point T1 of 250° C. or higher. Therefore, the element X1 preferably includes at least one element selected from Cr, Ru, Al, and Hf. The etching rate ER4 of the first hard mask film 14 including these elements is slow, the selectivity (ER3/ER4) is sufficiently large, and the processing of the phase shift film 13 is easy.

The first hard mask film 14 may contain a compound of the element X1. The compound of the element X1 contains, for example, at least one element selected from O, N, C, and B. By adding at least one element selected from O, N, C, and B, crystallization of the first hard mask film 14 can be suppressed, and roughness of the side surface of the opening of the first hard mask film 14 can be reduced.

Since Cr as the element X1 causes an increase in the side etching amount E, it is preferable that the element X1 be a metal compound containing a metal element other than Cr or a Cr compound containing non-metal element.

In step S201, the film thickness t1 of the first hard mask film 14 is preferably 5 nm to 40 nm. In a case where the film thickness t1 of the first hard mask film 14 is 5 nm or more, the first hard mask film 14 remains sufficiently at the end of the processing of the phase shift film 13. In a case where the film thickness t1 of the first hard mask film 14 is 40 nm or less, the first etching gas is likely to enter the opening of the first hard mask film 14, and the phase shift film 13 is likely to be etched.

The second hard mask film 15 preferably contains, as a metal element or a metalloid element, an element X2 having a melting point T2 of 1000° C. or higher for oxides. In a case where the melting point T2 is 1,000° C. or higher, the etching rate ER2 of the second hard mask film 15 is slow, the selectivity (ER1/ER2) is sufficiently large, and the first hard mask film 14 is easily processed. The melting point T2 is preferably 3,000° C. or lower. Table 2 shows the melting points of the oxides under atmospheric pressure.

TABLE 2

Compound

| | Chemical | Melting point |
|---|---|---|
| Pure substance | Formula | [° C.] |
| W | WO₂ | 1500 to 1600 |
| | WO₃ | 1473 |
| Hf | HfO₂ | 2800 |
| Ti | TiO | 1770 |
| | Ti₂O₃ | 1842 |
| | TiO₂ | 1843 |
| Nb | NbO | 1937 |
| | NbO₂ | 1901 |
| | Nb₂O₅ | 1500 |
| Ta | Ta₂O₅ | 1875 |
| Si | SiO₂ | 1722 |
| Sn | SnO | 1080 |
| | SnO₂ | 1630 |

As shown in Table 2, Ta, Si, Ti, W, Sn, and Nb have a melting point T2 of 250° C. or higher. Therefore, the element X2 preferably includes at least one element selected from Ta, Si, Ti, W, Sn, and Nb. The etching rate ER2 of the second hard mask film 15 containing these elements is slow, the selectivity (ER1/ER2) is sufficiently large, and the first hard mask film 14 is easily processed. In addition, the element X2 more preferably includes at least one element selected from Ta, Ti, W, Sn, and Nb.

The second hard mask film 15 may contain a compound of the element X2. The compound of the element X2 contains, for example, at least one element selected from O, N, C, and B. By adding at least one element selected from O, N, C, and B, crystallization of the second hard mask film 15 can be suppressed, and roughness of the side surface of the opening of the second hard mask film 15 can be reduced.

Table 3 shows an example of a relationship between a chemical composition (volume ratio) of the second etching gas, a chemical composition (molar ratio) of the first hard mask film 14, a chemical composition (molar ratio) of the second hard mask film 15, and the selectivity (ER1/ER2).

TABLE 3

| | Second etching gas | | | | | | |
|---|---|---|---|---|---|---|---|
| | First hard mask film | | | Second hard mask film | | | |
| | Film | | ER1 | Film | | ER2 | Selectivity |
| Composition | type | Composition | [nm/min] | type | Composition | [nm/min] | ER1/ER2 |
| Cl₂:O₂ = | Ru | — | 59.7 | TaON | Ta:O:N = | 0.3 | 199 |
| 50:50 | | | | | 38:55:7 | | |
| | RuCr | Ru:Cr = | 24.7 | | | | 82 |
| | | 80:20 | | | | | |
| | RuCr | Ru:Cr = | 21.4 | | | | 71 |
| | | 60:40 | | | | | |
| | RuCr | Ru:Cr = | 15.3 | | | | 51 |
| | | 40:60 | | | | | |
| Cl₂:O₂ = | CrN | Cr:N = | 31.2 | | | | 104 |
| 80:20 | | 90:10 | | | | | |
| | CrO | Cr:O = | 64.8 | | | | 216 |
| | | 40:60 | | | | | |

All of the selectivities (ER1/ER2) shown in Table 3 are 10 or more.

In step S201, the film thickness t2 of the second hard mask film 15 is preferably 2 nm to 20 nm. In a case where the film thickness t2 of the second hard mask film 15 is 2 nm or more, the second hard mask film 15 remains sufficiently at the end of the processing of the first hard mask film 14. In a case where the film thickness t2 of the second hard mask film 15 is 20 nm or less, the second etching gas is likely to enter the opening of the second hard mask film 15, and the first hard mask film 14 is likely to be etched.

In step S201, a ratio (t1/t2) of the film thickness (t1) of the first hard mask film 14 to the film thickness (t2) of the second hard mask film 15 is preferably 1 to 40. In a case where the ratio (t1/t2) is 1 or more, the film thickness (t2) of the second hard mask film 15 is sufficiently small, and processing time of the second hard mask film 15 is short. In a case where the ratio (t1/t2) is 40 or less, the film thickness (t1) of the first hard mask film 14 is sufficiently small, the processing time of the first hard mask film 14 can be shortened during the processing, and there is a slight concern that the pattern end portion of the second hard mask film 15 will be eroded. The ratio (t1/t2) is more preferably 2 to 10, still more preferably 2.5 to 10, and particularly preferably 3 to 10.

Next, the substrate 10, the multilayer reflective film 11, the protective film 12, and the phase shift film 13 will be described in this order with reference to FIG. 1 again. Note that the first hard mask film 14 and the second hard mask film 15 are as described above.

The substrate 10 is, for example, a glass substrate. The material of the substrate 10 is preferably quartz glass containing TiO₂. Quartz glass has a small linear expansion coefficient and a small dimensional change due to a temperature change compared with general soda-lime glass. The quartz glass may contain 80% by mass to 95% by mass of SiO₂ and 4% by mass to 17% by mass of TiO₂. In a case where the TiO₂ content is 4% by mass to 17% by mass, a linear expansion coefficient near room temperature is substantially zero, and a dimensional change near room temperature hardly occurs. The quartz glass may contain a third component or an impurity other than SiO₂ and TiO₂. The material of the substrate 10 may be crystallized glass in which a β-quartz solid solution is precipitated, silicon, metal, or the like.

The substrate 10 has the first main surface 10a and the second main surface 10b facing a side opposite to the first main surface 10a. The multilayer reflective film 11 or the like is formed on the first main surface 10a. The size of the substrate 10 in plan view (when viewed in the Z-axis direction) is, for example, 152 mm in length and 152 mm in width. A vertical dimension and a horizontal dimension may be 152 mm or more. Each of the first main surface 10a and the second main surface 10b has, for example, a square quality assurance region at a center thereof. A size of the quality assurance region is, for example, 142 mm in length and 142 mm in width. The quality assurance region of the first main surface 10a preferably has a root-mean-square roughness (Rq) of 0.15 nm or less and a flatness of 100 nm or less. In addition, it is preferable that the quality assurance region of the first main surface 10a not have a defect that causes a phase defect.

The multilayer reflective film 11 reflects EUV light. The multilayer reflective film 11 is, for example, a film in which a high refractive index layer and a low refractive index layer are alternately laminated. A material of the high refractive index layer is, for example, silicon (Si), a material of the low refractive index layer is, for example, molybdenum (Mo), and an Mo/Si multilayer reflective film is used. Note that an Ru/Si multilayer reflective film, an Mo/Be multilayer reflective film, an Mo compound/Si compound multilayer reflective film, an Si/Mo/Ru multilayer reflective film, an Si/Mo/Ru/Mo multilayer reflective film, an Si/Ru/Mo/Ru multilayer reflective film, an Si/Ru/Mo multilayer reflective film, and the like can also be used as the multilayer reflective film 11.

The film thickness of each layer constituting the multilayer reflective film 11 and the number of repeating units of the layer can be appropriately selected in correspondence with the material of each layer and the reflectance to EUV light. In a case where the multilayer reflective film 11 is an Mo/Si multilayer reflective film, to achieve a reflectance of 60% or more with respect to EUV light having an incidence angle θ (refer to FIG. 7) of 6°, an Mo layer having a film thickness of 2.3±0.1 nm and an Si layer having a film thickness of 4.5±0.1 nm may be laminated such that the number of repeating units is 30 or more and 60 or less. The multilayer reflective film 11 preferably has a reflectance of 60% or more with respect to the EUV light at an incidence angle θ of 6°. The reflectance is more preferably 65% or more.

Examples of methods for forming each layer constituting the multilayer reflective film 11 include a DC sputtering method, a magnetron sputtering method, an ion beam sputtering method and the like. In a case where the Mo/Si multilayer reflective film is formed using an ion beam sputtering method, examples of film formation conditions for each of the Mo layer and the Si layer are as follows.

### <Film Formation Conditions of Si Layer>

Target: Si target,
Sputtering gas: Ar gas,
Gas pressure: 1.3×10⁻² Pa to 2.7×10⁻² Pa,
Ion acceleration voltage: 300 V to 1,500 V,
Film formation rate: 0.030 nm/sec to 0.300 nm/sec,
Film thickness of Si layer: 4.5±0.1 nm.

### <Film Formation Conditions of Mo Layer>

Target: Mo target,
Sputtering gas: Ar gas,
Gas pressure: 1.3×10⁻² Pa to 2.7×10⁻² Pa,
Ion acceleration voltage: 300 V to 1,500 V,
Film formation rate: 0.030 nm/sec to 0.300 nm/sec,
Film thickness of Mo layer: 2.3±0.1 nm.

### <Repeating Unit of Si Layer and Mo Layer>

Number of repeating units: 30 to 60 (preferably 40 to 50).

The protective film 12 is formed between the multilayer reflective film 11 and the phase shift film 13, and protects the multilayer reflective film 11. The protective film 12 protects the multilayer reflective film 11 from the first etching gas during the processing of the phase shift film 13, that is, in step S204. The protective film 12 remains on the multilayer reflective film 11 without being removed even after being exposed to the first etching gas.

The protective film 12 contains, for example, at least one element selected from Ru, Rh, and Si. In a case where the protective film 12 contains Rh, the protective film 12 may contain only Rh or may contain an Rh compound. The Rh compound may contain at least one element Z1 selected from Ru, Nb, Mo, Ta, Ir, Pd, Zr, Y, and Ti in addition to Rh.

By adding Ru, Nb, Mo, Zr, Y, or Ti to Rh, the extinction coefficient can be reduced while suppressing an increase in refractive index, and the reflectance with respect to EUV light can be improved. In addition, by adding Ta, Ir, Pd, or Y to Rh, resistance to the first etching gas can be improved.

The Rh compound may contain at least one element Z2 selected from N, O, C, and B in addition to Rh. The element Z2 reduces resistance of the protective film 12 to the first etching gas, but reduces crystallinity of the protective film 12 to improve smoothness of the protective film 12. The Rh compound containing the element Z2 has a noncrystalline structure or a microcrystalline structure. In a case where the Rh compound has the noncrystalline structure or the microcrystalline structure, an X-ray diffraction profile of the Rh compound does not have a clear peak.

The protective film 12 may be a film consisting of a single layer or may be a multilayer film including a lower layer and an upper layer. A lower layer of the protective film 12 is a layer formed in contact with the uppermost surface of the multilayer reflective film 11. An upper layer of the protective film 12 is in contact with the lowermost surface of the phase shift film 13. As described above, by employing the multi-layer structure of the protective film 12, a material having excellent predetermined function can be used for each layer, and thus multifunctionality of the entire protective film 12 can be achieved.

The upper layer of the protective film 12 preferably contains Rh, and more preferably contains an Rh compound. The lower layer of the protective film 12 preferably contains at least one element selected from Ru, Nb, Mo, Zr, Y, C, and B, and more preferably contains Ru. In addition, in a case where the protective film 12 is a multilayer film, the thickness of the protective film 12 means the total film thickness of the multilayer film.

The thickness of the protective film 12 is preferably 1.0 nm to 4.0 nm, more preferably 2.0 nm to 3.5 nm, and still more preferably 2.5 nm to 3.0 nm. In a case where the thickness of the protective film 12 is 1.0 nm or more, etching resistance is satisfactory. In addition, in a case where the thickness of the protective film 12 is 4.0 nm or less, the reflectance with respect to EUV light is satisfactory.

A density of the protective film 12 is preferably 10.0 g/cm³ to 14.0 g/cm³. In a case where the density of the protective film 12 is 10.0 g/cm³ or more, the etching resistance is satisfactory. In addition, in a case where the density of the protective film 12 is 14.0 g/cm³ or less, a decrease in reflectance with respect to EUV light can be suppressed.

The root-mean-square roughness Rq of the upper surface of the protective film 12, that is, the surface of the protective film 12 on which the phase shift film 13 is formed is preferably 0.20 nm or less and more preferably 0.17 nm or less. In a case where the root-mean-square roughness Rq is 0.20 nm or less, the phase shift film 13 or the like can be smoothly formed on the protective film 12. In addition, scattering of EUV light can be suppressed, and the reflectance to EUV light can be improved. The root-mean-square roughness Rq is preferably 0.05 nm or more.

Examples of methods for forming the protective film 12 include a DC sputtering method, a magnetron sputtering method, an ion beam sputtering method, and the like. In a case where the Rh film is formed by the DC sputtering method, an example of the film formation conditions is as follows.

### <Film Formation Condition for Rh Film>

Target: Rh target,
Sputtering gas: Ar gas,
Gas pressure: 1.0×10⁻² Pa to 1.0×10⁰ Pa,
Output density of target: 1.0 W/cm² to 8.5 W/cm²,
Film formation rate: 0.020 nm/sec to 1.000 nm/sec,
Film thickness: 1 nm to 10 nm.

The phase shift film 13 is a film in which the opening pattern 13a is to be formed. The opening pattern 13a is not formed in the manufacturing step of the reflective mask blank 1, but is formed in the manufacturing step of the reflective mask 2. The phase shift film 13 shifts the phase of the second EUV light L2 with respect to first EUV light L1 shown in FIG. 7.

The first EUV light L1 is light that passes through the opening pattern 13a without being transmitted through the phase shift film 13, is reflected by the multilayer reflective film 11, and passes through the opening pattern 13a again without being transmitted through the phase shift film 13. Second EUV light L2 is light that is transmitted through the phase shift film 13 while being absorbed by the phase shift film 13, is reflected by the multilayer reflective film 11, and is transmitted through the phase shift film 13 while being absorbed by the phase shift film 13 again.

A phase difference (>0) between the first EUV light L1 and the second EUV light L2 is, for example, 170° to 250°. The phase of the first EUV light L1 may be advanced or delayed with respect to the phase of the second EUV light L2. The phase shift film 13 improves contrast of a transferred image using interference of the first EUV light L1 and the second EUV light L2. The transferred image is an image obtained by transferring the opening pattern 13a of the phase shift film 13 to the target substrate.

In EUVL, a so-called projection effect (shadowing effect) occurs. The shadowing effect refers to, due to the fact that an incidence angle θ of the EUV light is not 0° (for example, 6°), a region where the EUV light is blocked by a side wall being generated in the vicinity of a side wall of the opening pattern 13a, and a positional shift or a dimensional shift of the transferred image occurs. To reduce the shadowing effect, it is effective to reduce a height of the side wall of the opening pattern 13a, and it is effective to thin the phase shift film 13.

The film thickness of the phase shift film 13 is, for example, 60 nm or less and preferably 50 nm or less to reduce the shadowing effect. The film thickness of the phase shift film 13 is preferably 20 nm or more and more preferably 30 nm or more to secure a phase difference between the first EUV light L1 and the second EUV light L2.

To reduce the shadowing effect while securing the phase difference between the first EUV light L1 and the second EUV light L2, it is effective to reduce a refractive index n of the phase shift film 13 in order to reduce the film thickness of the phase shift film 13. In addition, to reduce the reflectance with respect to EUV light, it is effective to increase an extinction coefficient k of the phase shift film 13. As described above, the phase shift film 13 is required to have excellent optical characteristics.

The refractive index n of the phase shift film 13 is preferably 0.940 or less, more preferably 0.930 or less, still more preferably 0.929 or less, particularly preferably 0.925 or less, more particularly preferably 0.920 or less, still more particularly preferably 0.918 or less, even still more particularly preferably 0.910 or less, and most preferably 0.900 or less. As the refractive index n of the phase shift film 13 decreases, the phase shift film 13 can be thinned. The refractive index n of the phase shift film 13 is preferably 0.885 or more. In the present specification, the refractive index is a refractive index with respect to EUV light (for example, light having a wavelength of 13.5 nm).

The extinction coefficient k of the phase shift film 13 is preferably 0.030 or more, more preferably 0.034 or more, still more preferably 0.036 or more, and particularly preferably 0.038 or more. As the extinction coefficient k of the phase shift film 13 increases, it is easy to obtain a desired reflectance with a thin film thickness. The extinction coefficient k of the phase shift film 13 is preferably 0.065 or less. In the present specification, the extinction coefficient is an extinction coefficient with respect to EUV light (for example, light having a wavelength of 13.5 nm).

As the optical characteristics (the refractive index n and the extinction coefficient k) of the phase shift film 13, a value of a database of Center for X-Ray Optics, Lawrence Berkeley National Laboratory or a value calculated from “incidence angle dependence” of a reflectance to be described below is used.

The incidence angle θ of the EUV light, a reflectance R with respect to the EUV light, the refractive index n of the phase shift film 13, and the extinction coefficient k of the phase shift film 13 satisfy the following Expression (1).

$$R = \vert sin θ - {( {( n + ik )}^{2} - {cos}^{2} θ )}^{1 / 2} ) / ( sin θ + {( {( n + ik )}^{2} - {cos}^{2} θ )}^{1 / 2} ) \vert \qquad ( 1 )$$

A combination of the incidence angle θ and the reflectance R is measured a plurality of times, and the refractive index n and the extinction coefficient k are calculated by the least squares method such that an error between a plurality of pieces of measurement data and Expression (1) is minimized.

The phase shift film 13 preferably contains a noble metal element. The noble metal element is, for example, Ir, Pt, Pd, Ag, or Au. Since these noble metal elements have a relatively small refractive index, the film thickness of the phase shift film 13 can be reduced while securing a phase difference. However, these noble metal elements have a slow etching rate. Therefore, in the present embodiment, the first hard mask film 14 and the second hard mask film 15 are formed on the phase shift film 13 in this order.

The phase shift film 13 preferably has a layer consisting of an Ir-based material. The phase shift film 13 is a single layer in the present embodiment, but may be a plurality of layers. In any case, it is preferable that at least one layer constituting the phase shift film 13 consist of the Ir-based material. The Ir-based material is a material containing Ir as a main component. The Ir-based material preferably contains 25 at % to 100 at % of Ir, more preferably 30 at % to 100 at % of Ir, still more preferably 40 at % to 100 at % of Ir, and particularly preferably 50 at % to 100 at % of Ir. The Ir-based material may be an Ir single substance, but is preferably an Ir compound.

The Ir compound preferably contains at least one element selected from O, B, C, and N. By adding at least one element selected from O, B, C, and N, crystallization can be suppressed while suppressing deterioration of optical characteristics, and roughness of the side surface of the opening pattern 13a can be reduced. The Ir compound preferably contains O, and more preferably contains O and N.

In some cases, the reflective mask 2 may be exposed to a hydrogen gas inside of an EUV exposure device. The hydrogen gas is used, for example, for the purpose of reducing carbon contamination. Accordingly, the phase shift film 13 may be exposed to the hydrogen gas.

O, B, C, or N contained in the Ir compound can react with the hydrogen gas to generate a hydride (for example, H₂O). In a case where the hydride is generated, the hydride has high volatility, O, B, C, or Nis eliminated from the Ir compound, and the film thickness of the phase shift film 13 is reduced. A change in film thickness leads to a change in phase difference.

Therefore, the Ir compound preferably contains at least one element selected from Ta, Cr, Mo, W, Re, and Si. By adding these elements, hydrogen resistance can be improved. Among these elements, Ta, Cr, W, and Re can improve the hydrogen resistance while suppressing deterioration of the optical characteristics. In addition, the hydrogen resistance can be further improved by Mo and Si.

Examples of methods for forming the phase shift film 13 include a DC sputtering method, a magnetron sputtering method, or an ion beam sputtering method. The oxygen content of the phase shift film 13 can be controlled by the content of an O₂ gas in the sputtering gas. In addition, the nitrogen content of the phase shift film 13 can be controlled by the content of an N₂ gas in the sputtering gas.

In a case where an IrTaON film is formed by a reactive sputtering method, examples of film formation conditions are as follows.

### <Film Formation Condition for IrTaON Film>

Target: Ir target and Ta target (or IrTa target),
Output density of Ir target: 1.0 W/cm² to 8.5 W/cm²,
Output density of Ta target: 1.0 W/cm² to 8.5 W/cm²,
Sputtering gas: mixed gas of Ar gas, O₂ gas, and N₂ gas,
Volume ratio of O₂ gas in sputtering gas (O₂/(Ar+O₂+N₂)): 0.01 to 0.25,
Volume ratio of N₂ gas in sputtering gas (N₂/(Ar+O₂+N₂)): 0.01 to 0.25,
Film formation rate: 0.020 nm/sec to 0.060 nm/sec,
Film thickness: 20 nm to 60 nm

The protective film 12 has higher resistance to the first etching gas compared with the phase shift film 13. The protective film 12 and the phase shift film 13 preferably have a selectivity (ER3/ER5) of 5 or more to the first etching gas. ER3 is an etching rate of the phase shift film 13, and ER5 is an etching rate of the protective film 12. The larger the selectivity (ER3/ER5), the better the workability of the phase shift film 13. The selectivity (ER3/ER5) is preferably 5.0 or more, more preferably 10 or more, and still more preferably 30 or more. The selectivity (ER3/ER5) is preferably 200 or less and more preferably 100 or less.

### EXAMPLES

Hereinafter, experimental data will be described. In Example 1 and Example 2, as shown in FIG. 5A, a reflective mask blank 1 including the second hard mask film 15 between the first hard mask film 14 and the resist film 16 was prepared, and the processing of the second hard mask film 15 (Step S202) and the processing of the first hard mask film 14 (Step S203) were performed. On the other hand, in Example 3, as shown in FIG. 6A, a reflective mask blank 1 not including the second hard mask film 15 was prepared, and the first hard mask film 14 was processed (step S203). After step S203 and before step S204, a cross-section was observed with a scanning electron microscope (SEM), and the side etching amount E and the taper angle α were measured. Example 1 and Example 2 are examples, and Example 3 is a comparative example. In Examples 1 to 3, the substrate 10, the multilayer reflective film 11, the protective film 12, the phase shift film 13, and the resist film 16 had the same configuration.

As the substrate 10, a SiO₂—TiO₂ based glass substrate (outer shape: 6 inches (152 mm) square, thickness: 6.3 mm) was prepared. This glass substrate had a thermal expansion coefficient of 0.02×10⁻⁷/° C. at 20° C., a Young's modulus of 67 GPa, a Poisson's ratio of 0.17, and a specific rigidity of 3.07×10⁷ m²/s². The quality assurance region of the first main surface 10a of the substrate 10 had a root-mean-square roughness (Rq) of 0.15 nm or less and a flatness of 100 nm or less by polishing. A Cr film having a thickness of 100 nm was formed on the second main surface 10b of the substrate 10 by a magnetron sputtering method. Sheet resistance of the Cr film was 100 Ω/□.

A Mo/Si multilayer reflective film was formed as the multilayer reflective film 11. The Mo/Si multilayer reflective film was formed by repeating formation of a Si layer (film thickness: 4.5 nm) and a Mo layer (film thickness: 2.3 nm) 40 times using an ion beam sputtering method. The total film thickness of the Mo/Si multilayer reflective film was 272 nm ((4.5 nm+2.3 nm)×40).

As the protective film 12, an Rh film (film thickness: 5 nm) was formed. The Rh film was formed by an ion beam sputtering method.

As the phase shift film 13, an IrTaON film (film thickness: 35 nm) was formed. The IrTaON film was formed by a binary sputtering method. A chemical composition of the IrTaON film was measured using an X-ray photoelectron spectrometer (PHI 5000 VersaProbe) manufactured by ULVAC-PHI, Inc. The chemical composition (molar ratio) of the IrTaON film was Ir:Ta:O:N=71.4:6.1:20.5:2.0.

In Example 1 and Example 3, a Cr film was formed as the first hard mask film 14. The Cr film was formed by a magnetron sputtering method. The film thickness of the Cr film of Example 1 was 25 nm, and the film thickness of the Cr film of Example 3 was 20 nm. On the other hand, in Example 2, an RuCr film was formed as the first hard mask film 14. The RuCr film was formed using a binary sputtering method. A chemical composition (molar ratio) of the RuCr film was Ru:Cr=60:40. The film thickness of the RuCr film was 25 nm.

In Example 1 and Example 2, a TaON film (film thickness: 5 nm) was formed as the second hard mask film 15 differently from Example 3. The TaON film was formed by a reactive sputtering method. A chemical composition of the TaON film was measured using the X-ray photoelectron spectrometer (PHI 5000 VersaProbe) manufactured by ULVAC-PHI, Inc. A chemical composition (molar ratio) of the TaON film was Ta:O:N=38:55:7.

Table 4 shows experimental conditions and experimental results of Examples 1 to 3.

TABLE 4

| | | Example 1 | Example 2 | Example 3 |
|---|---|---|---|---|
| First hard mask layer | Film type | Cr | RuCr | Cr |
| | Film composition | — | Ru:Cr = 60:40 | — |
| | Film thickness | 25 | 25 | 20 |
| | [nm] | | | |
| Second etching gas | | Cl₂ + O₂ | | |
| ER1/ER2 | | 104 | 71 | — |
| Second hard mask | Film type | TaON | | — |
| layer | Film composition | Ta:O:N = 38:55:7 | | |
| | Film thickness | 5 | | |
| | [nm] | | | |

| Third etching gas | CF₄ + CHF₃ | | |
|---|---|---|---|
| E [nm] | 5.7 | 3.4 | — |
| α [°] | 87 | 81 | 39 |

| | | |
|---|---|---|
| t1/t2 | 5 | — |

In Table 4, it can be seen that, by providing the second hard mask film 15, the side surface of the opening of the first hard mask film 14 can be made orthogonal, and the taper angle α can be increased by comparing Example 1 and Example 2, and Example 3 with each other. In addition, in Table 4, it can be seen that, in a case where the first hard mask film 14 consists of a Cr compound instead of a single substance of Cr, the side etching amount E can be reduced by comparing Example 1 and Example 2 with each other.

Hereinabove, the reflective mask blank, the method for manufacturing the reflective mask blank, and the method for manufacturing the reflective mask according to the present disclosure have been described, but the present disclosure is not limited to the above-described embodiment and the like. Various changes, modifications, substitutions, additions, deletions, and combinations can be made within the scope described in the appended claims. These also obviously belong to the technical scope of the present disclosure.

Priority is claimed on Japanese Patent Application No. 2023-074391, filed on Apr. 28, 2023, the content of which is incorporated herein by reference.

### REFERENCE SIGNS LIST

1 Reflective mask blank
2 Reflective mask
10 Substrate
11 Multilayer reflective film
12 Protective film
13 Phase shift film
14 First hard mask film
15 Second hard mask film

1. A reflective mask blank comprising, in the following order:
a substrate;
a multilayer reflective film;
a protective film;
a phase shift film;
a first hard mask film; and
a second hard mask film,
wherein the multilayer reflective film reflects EUV light,
the protective film protects the multilayer reflective film from a first etching gas during processing of the phase shift film,
the phase shift film absorbs the EUV light and shifts a phase of the EUV light,
the first hard mask film protects part of the phase shift film from the first etching gas during the processing of the phase shift film,
the second hard mask film protects part of the first hard mask film from a second etching gas during processing of the first hard mask film,
the first hard mask film has higher resistance to the first etching gas containing a fluorine-based gas compared with the phase shift film,
the second hard mask film has higher resistance to the second etching gas containing an oxygen-based gas and a chlorine-based gas compared with the first hard mask film,
a selectivity (ER1/ER2) of the second hard mask film and the first hard mask film to the second etching gas is 5 or more,
ER1 is an etching rate of the first hard mask film, and
ER2 is an etching rate of the second hard mask film.

2. The reflective mask blank according to claim 1,
wherein the first hard mask film contains, as a metal element, an element X1 having a melting point of 250° C. or higher for a fluoride having a valence of 4 or less.

3. The reflective mask blank according to claim 2,
wherein the element X1 includes at least one element selected from Cr, Ru, Al, and Hf.

4. The reflective mask blank according to claim 1,
wherein the second hard mask film contains, as a metal element or a metalloid element, an element X2 having a melting point of 1,000° C. or higher for an oxide.

5. The reflective mask blank according to claim 4,
wherein the element X2 includes at least one element selected from Ta, Si, Ti, W, Sn, and Nb.

6. The reflective mask blank according to claim 4,
wherein the element X2 includes at least one element selected from Ta, Ti, W, Sn, and Nb.

7. The reflective mask blank according to claim 4,
wherein the second hard mask film contains a compound of the element X2, and the compound of the element X2 includes at least one element selected from O, N, C, and B.

8. The reflective mask blank according to claim 1,
wherein a film thickness of the first hard mask film is 5 nm to 40 nm.

9. The reflective mask blank according to claim 1,
wherein a film thickness of the second hard mask film is 2 nm to 20 nm.

10. The reflective mask blank according to claim 1,
wherein a ratio (t1/t2) of a film thickness (t1) of the first hard mask film to a film thickness (t2) of the second hard mask film is 1 to 40.

11. The reflective mask blank according to claim 1,
wherein the first hard mask film and the phase shift film have a selectivity (ER3/ER4) of 2 or more to the first etching gas, and
ER3 is an etching rate of the phase shift film, and ER4 is an etching rate of the first hard mask film.

12. The reflective mask blank according to claim 1,
wherein the phase shift film contains at least one element selected from Ir, Pt, Pd, Ag, and Au.

13. The reflective mask blank according to claim 11,
wherein the phase shift film contains Ir as a main component.

14. The reflective mask blank according to claim 1,
wherein the protective film contains at least one element selected from Ru, Rh, and Si.

15. The reflective mask blank according to claim 1,
wherein the protective film contains Rh.

16. The reflective mask blank according to claim 1,
wherein the protective film is a multilayer film including a lower layer and an upper layer, and the upper layer contains Rh.

17. The reflective mask blank according to claim 1, further comprising:
a buffer film between the protective film and the phase shift film.

18. A method for manufacturing a reflective mask blank, comprising:
forming a multilayer reflective film, a protective film, a phase shift film, a first hard mask film, and a second hard mask film on a substrate in this order,
wherein the multilayer reflective film reflects EUV light,
the protective film protects the multilayer reflective film from a first etching gas during processing of the phase shift film,
the phase shift film absorbs the EUV light and shifts a phase of the EUV light,
the first hard mask film protects part of the phase shift film from the first etching gas during the processing of the phase shift film,
the second hard mask film protects part of the first hard mask film from a second etching gas during processing of the first hard mask film,
the first hard mask film has higher resistance to the first etching gas containing a fluorine-based gas compared with the phase shift film,
the second hard mask film has higher resistance to the second etching gas containing an oxygen-based gas and a chlorine-based gas compared with the first hard mask film,
a selectivity (ER1/ER2) of the second hard mask film and the first hard mask film to the second etching gas is 5 or more,
ER1 is an etching rate of the first hard mask film, and
ER2 is an etching rate of the second hard mask film.

19. A method for manufacturing a reflective mask, comprising:
preparing the reflective mask blank according to claim 1; and
forming an opening pattern in the phase shift film.

20. The method for manufacturing a reflective mask according to claim 19, further comprising:
transferring an opening pattern of a resist film formed in advance on the second hard mask film to the second hard mask film using a third etching gas containing a fluorine-based gas;
transferring an opening pattern of the second hard mask film to the first hard mask film using the second etching gas; and
transferring an opening pattern of the first hard mask film to the phase shift film using the first etching gas.

21. The method for manufacturing a reflective mask according to claim 20, further comprising:
removing the second hard mask film before the opening pattern of the first hard mask film is transferred to the phase shift film after the opening pattern of the second hard mask film is transferred to the first hard mask film.

22. The method for manufacturing a reflective mask according to claim 21,
wherein a gas containing a fluorine-based gas is used to remove the second hard mask film.

23. The method for manufacturing a reflective mask according to claim 20, further comprising:
removing the first hard mask film after transferring the opening pattern of the first hard mask film to the phase shift film.

24. The method for manufacturing a reflective mask according to claim 23,
wherein a gas containing a chlorine-based gas and an oxygen-based gas is used to remove the first hard mask film.
